(19) United States
(12) Patent Application Publication
(10) Pub. No.: US 2025/0178158 A1
(43) Pub. Date: Jun. 5, 2025

(54) SUBSTRATE POLISHING METHOD AND SUBSTRATE POLISHING APPARATUS

(71) Applicant: EBARA CORPORATION, Tokyo (JP)

(72) Inventors: Masashi KABASAWA, Tokyo (JP); Keita YAGI, Tokyo (JP)

(21) Appl. No.: 18/967,350

(22) Filed: Dec. 3, 2024

(30) Foreign Application Priority Data
Dec. 4, 2023 (JP) 2023-204613

(51) Int. Cl. B24B 49/18; B24B 53/017

(52) U.S. Cl. CPC B24B 49/18; B24B 53/017

(57) ABSTRACT

A first dressing of dressing a polishing member is performed under a plurality of preset set dress conditions, a first cut rate of the polishing member is measured based on a measurement value of a surface height of the polishing member for each set dress condition, and the set dress condition and the first cut rate are associated with each other and stored as relationship data. The substrate is polished by applying a first dress condition corresponding to a target cut rate based on the relationship data, and a second cut rate of the polishing member is measured based on the measurement value of the surface height of polishing member. A second dress condition corresponding to the target cut rate is acquired based on a change of the second cut rate from the target cut rate and the relationship data, and substrate is polished by applying the second dress condition.

### BACKGROUND

### Technical Field

The present invention relates to a substrate polishing method and a substrate polishing apparatus for polishing a substrate such as a wafer.

### Related Art

As one of methods for planarizing a surface of a substrate for a semiconductor device, there is polishing by a chemical mechanical polishing (CMP) apparatus. The chemical mechanical polishing apparatus has a polishing member (polishing cloth, polishing pad, or the like) and a holding unit (top ring, polishing head, chuck, or the like) that holds an object to be polished such as a substrate. Then, the surface (surface to be polished) of the object to be polished is pressed against the surface of the polishing member, and the polishing member and the object to be polished are relatively moved while a polishing liquid (abrasive liquid, chemical liquid, slurry, pure water, or the like) is supplied between the polishing member and the object to be polished, so that the surface of the object to be polished is polished flat.

As a material of such a polishing member, a foamed resin or a nonwoven fabric having fine irregularities formed on a surface thereof is generally used. The fine irregularities act as a chip pocket effective for preventing clogging and reducing polishing resistance. However, when the object to be polished is continuously polished with the polishing member, fine irregularities on the surface of the polishing member are crushed, and a polishing rate is lowered. Therefore, the surface of the polishing member is subjected to dressing (setting) with a dresser in which a large number of abrasive grains such as diamond grains are electrodeposited, and fine irregularities are reformed on the surface of the polishing member.

In the dressing of the polishing member, since the rotating dresser is pressed against the polishing member while being moved in a radial direction of the polishing member, the surface of the polishing member is scraped off although the amount is small. Therefore, when the dressing is not appropriately performed, inappropriate undulation occurs on the surface of the polishing member, which causes variation in the polishing rate with respect to the surface to be polished of the substrate, and thus the dressing needs to be appropriately performed.

For example, JP 2010-162688 A discloses a dressing method for a polishing pad in which a cut rate measuring means for measuring a cut rate (a wear amount of the polishing pad per unit time) of a polishing pad by a dresser is provided, and the measured cut rate of the polishing pad is fed back to a dress condition for a dresser drive control means.

### SUMMARY

In JP 2010-162688 A, there is no description on how to specifically feed back the measured cut rate of the polishing pad to the dress condition. The dress condition is adjusted by adjusting a moving speed (a moving speed of the polishing pad in the radial direction) of the dresser passing over the polishing pad, but it is necessary to keep the total moving time of the dresser constant in order to prevent a decrease in throughput. Therefore, when the moving speed of the dresser at a radial position on the polishing pad is increased, it is necessary to decrease the moving speed of the dresser at another position, and it is difficult to appropriately maintain the cut rate of the polishing pad.

In addition, when the same dress condition is applied to the polishing pad having the same specification, it is ideal that the cut rates are the same, but in practice, the cut rate of the polishing pad may vary due to factors such as individual differences of the polishing pad, water absorption distribution of the polishing pad, and environment at the time of dressing. In addition, by repeating the dressing, the polishing pad and the dresser are worn, which may cause variations in the cut rate of the polishing pad. Therefore, in consideration of the variation in the cut rate, it is necessary to replace the polishing pad before the polishing pad reaches a predetermined wear amount.

An embodiment of the present invention is a substrate polishing method for polishing a substrate by bringing a polishing member used in a substrate polishing apparatus into contact with the substrate, the substrate polishing method including: performing a first dressing of dressing the polishing member under a plurality of preset dress conditions; measuring a first cut rate of the polishing member based on a measurement value of a surface height of the polishing member for each set dress condition; storing the set dress condition and the first cut rate in association with each other as relationship data; polishing a substrate by applying a first dress condition corresponding to a target cut rate, and measuring a second cut rate of the polishing member based on the measurement value of the surface height of the polishing member; correcting the relationship data based on a change amount of the second cut rate from the target cut rate, and acquiring a second dress condition corresponding to the target cut rate based on the corrected relationship data; and polishing the substrate by applying the second dress condition.

An embodiment of the present invention is a substrate polishing method for polishing a substrate by bringing a polishing member used in a substrate polishing apparatus into contact with the substrate, the substrate polishing method including: performing a first dressing of dressing the polishing member under a plurality of preset dress conditions; measuring a first cut rate of the polishing member based on a measurement value of a surface height of the polishing member for each set dress condition; storing the set dress condition and the first cut rate in association with each other as relationship data; polishing a substrate by applying a first dress condition corresponding to a target cut rate, and measuring a second cut rate of the polishing member based on the measurement value of the surface height of the polishing member; changing the target cut rate based on a change of the second cut rate from the target cut rate, and acquiring a second dress condition based on the relationship data corresponding to the target cut rate after the change; and polishing the substrate by applying the second dress condition.

### BRIEF DESCRIPTION OF DRAWINGS

FIG. 1 is a schematic view schematically illustrating a configuration of a substrate polishing apparatus;

FIG. 2 is a plan view schematically illustrating a dresser and a polishing pad;

FIG. 3 is a diagram illustrating an example of a scan area set on the polishing pad;

FIG. 4 is a block diagram illustrating an example of functional blocks of a dresser control unit that controls the operation of the dresser;

FIGS. 5A to 5C are explanatory diagrams illustrating an example of a dresser deformation amount (wear amount) when a dress load and a dress rotation speed are changed;

FIG. 6 is an explanatory diagram illustrating an example of the dress rotation speed and a cut rate;

FIG. 7 is an explanatory diagram illustrating an example of a relationship between a dress rotation speed and a dress load corresponding to a target cut rate;

FIG. 8 is an explanatory diagram illustrating an example of changing the dress condition;

FIG. 9 is a flowchart illustrating an example of cut rate setting processing;

FIG. 10 is a flowchart illustrating an example of substrate polishing and dressing process; and

FIG. 11 is a flowchart illustrating another example of the substrate polishing and dressing process.

### DETAILED DESCRIPTION

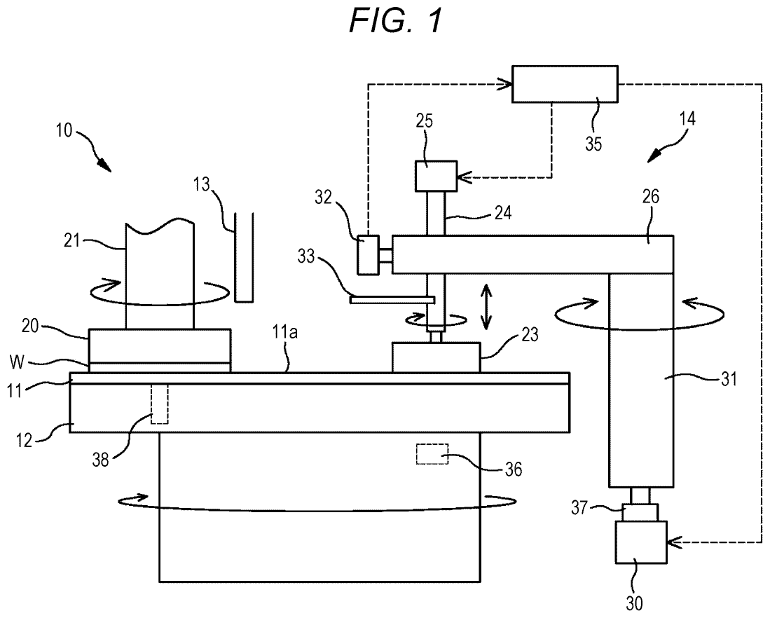

An embodiment of the present invention will be described with reference to the drawings. FIG. 1 is a schematic view illustrating a polishing apparatus for polishing a substrate such as a wafer. The polishing apparatus is provided in a substrate processing apparatus capable of performing a series of steps of polishing, cleaning, and drying the substrate W.

As illustrated in FIG. 1, the polishing apparatus includes a polishing unit 10 for polishing the substrate W, a polishing table 12 for holding a polishing pad (polishing member) 11, a polishing liquid supply nozzle 13 for supplying a polishing liquid onto the polishing pad 11, and a dressing unit 14 for conditioning (dressing) the polishing pad 11 used for polishing the substrate W.

The polishing unit 10 includes a top ring (substrate holding unit) 20 connected to a lower end of a top ring shaft 21. The top ring 20 is configured to hold the substrate W on a lower surface of the top ring by vacuum suction. The top ring shaft 21 is rotated by driving of a motor (not illustrated), and the top ring 20 and the substrate W are rotated by the rotation of the top ring shaft 21. The top ring shaft 21 moves up and down with respect to the polishing pad 11 by an up-down movement mechanism including, for example, a servomotor and a ball screw.

The polishing table 12 is connected to a motor (not illustrated) disposed below the polishing table. The polishing table 12 is rotated about an axis thereof by a motor. The polishing pad 11 is attached to the upper surface of the polishing table 12, and the upper surface of the polishing pad 11 forms a polishing surface 11a that is in contact with the substrate W.

Polishing of the substrate W is performed as follows. The top ring 20 and the polishing table 12 are rotated to supply a polishing liquid onto the polishing pad 11. In this state, the top ring 20 holding the substrate W is lowered, and the substrate W is pressed against the polishing surface 11a of the polishing pad 11 by a pressurizing mechanism (not illustrated) including an airbag installed in the top ring 20. The substrate W and the polishing pad 11 are brought into sliding contact with each other under the presence of a polishing liquid, whereby the surface of the substrate W is polished and planarized.

The dressing unit 14 includes a dresser 23 in contact with the polishing pad 11, a dresser shaft 24 connected to the dresser 23, an air cylinder 25 provided at an upper end of the dresser shaft 24, and a dresser arm 26 rotatably supporting the dresser shaft 24. Abrasive grains such as diamond grains are fixed to the lower surface of the dresser 23. The lower surface of the dresser 23 constitutes a dressing surface for dressing the polishing pad 11.

The dresser shaft 24 and the dresser 23 are movable up and down with respect to the dresser arm 26. The air cylinder 25 is a device that applies a load (dress load) to the polishing pad 11 to the dresser 23. The dress load is adjusted by the air pressure supplied to the air cylinder 25.

The dresser arm 26 is driven by the motor 30 to swing about a support shaft 31. The dresser shaft 24 is rotated by a motor (not illustrated) installed in the dresser arm 26, and the rotation of the dresser shaft 24 rotates the dresser 23 about the axis of the dresser. The air cylinder 25 presses the dresser 23 against the polishing surface 11a of the polishing pad 11 with a predetermined load via the dresser shaft 24.

Dressing of the polishing surface 11a of the polishing pad 11 is performed as follows. The polishing table 12 and the polishing pad 11 are rotated by a motor, and a dressing liquid (for example, pure water) is supplied from a dressing liquid supply nozzle (not illustrated) to the polishing surface 11a of the polishing pad 11. Further, the dresser 23 is rotated about the axis of the dresser. The dresser 23 is pressed against the polishing surface 11a by the air cylinder 25, and the lower surface (dressing surface) of the dresser 23 is brought into sliding contact with the polishing surface 11a. In this state, the dresser arm 26 is turned to swing the dresser 23 on the polishing pad 11 in the substantially radial direction of the polishing pad 11. The surface of the polishing pad 11 is scraped off by the rotating dresser 23.

A pad height sensor (surface height measuring instrument) 32 for measuring the height of the polishing surface 11a is fixed to the dresser arm 26. A sensor target 33 is fixed to the dresser shaft 24 so as to face a pad height sensor 32. The sensor target 33 moves up and down integrally with the dresser shaft 24 and the dresser 23, and the position of the pad height sensor 32 in an up-down direction is fixed. The pad height sensor 32 is a displacement sensor, and can indirectly measure the height of the polishing surface 11a (the thickness of the polishing pad 11) by measuring the displacement of the sensor target 33. Since the sensor target 33 is coupled to the dresser 23, the pad height sensor 32 can measure the height of the polishing surface 11a during conditioning of the polishing pad 11. The pad height sensor 32 may be configured not as a displacement sensor that measures the displacement of the sensor target 33 but as a distance sensor that directly measures the distance to the polishing pad 11.

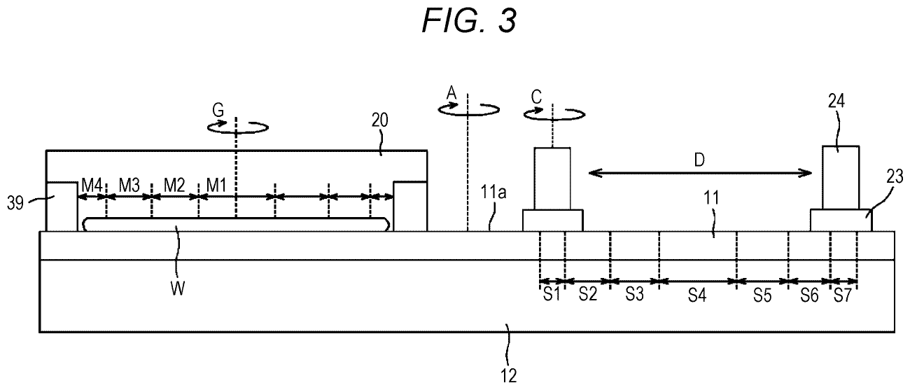

The pad height sensor 32 measures the height of the polishing surface 11a in a plurality of predetermined regions (monitor areas M1 to M7, refer to FIG. 3) divided in a radial direction of the polishing pad. The pad height sensor 32 indirectly measures the polishing surface 11a from the position in the up-down direction of the dresser 23 in contact with the polishing surface 11a. As a result, an average of the heights of the polishing surface 11a corresponding to the region (monitor area) in contact with the lower surface (dressing surface) of the dresser 23 is measured by the pad height sensor 32, and the height of the polishing pad is measured in a plurality of monitor areas, whereby a profile (cross-sectional shape of the polishing surface 11a) of the polishing pad can be obtained. As the pad height sensor 32, any type of sensor such as a linear scale sensor, a laser sensor, an ultrasonic sensor, or an eddy current sensor can be used.

The pad height sensor 32 is connected to a dresser control device (control unit) 35, and an output signal (that is, the measurement value of the height of the polishing surface 11a) of the pad height sensor 32 is transmitted to the dresser control device 35. The dresser control device 35 has a function of acquiring a height profile of the polishing pad 11 from a measurement value of the height of the polishing surface 11a, calculating a cut rate of the polishing pad 11, and controlling dress conditions (dress load, rotation speed) of the dresser 23 to be described later.

The polishing apparatus includes a table rotary encoder 36 that measures rotation angles of the polishing table 12 and the polishing pad 11, and a dresser rotary encoder 37 that measures a turning angle of the dresser 23. The table rotary encoder 36 and the dresser rotary encoder 37 are absolute encoders that measure absolute values of angles. These rotary encoders 36 and 37 are connected to a dresser control device 35, and the dresser control device 35 acquires information on the rotation angles of the polishing table 12 and the polishing pad 11 and the turning angle of the dresser 23 at the time of measuring the height of the polishing surface 11a by the pad height sensor 32.

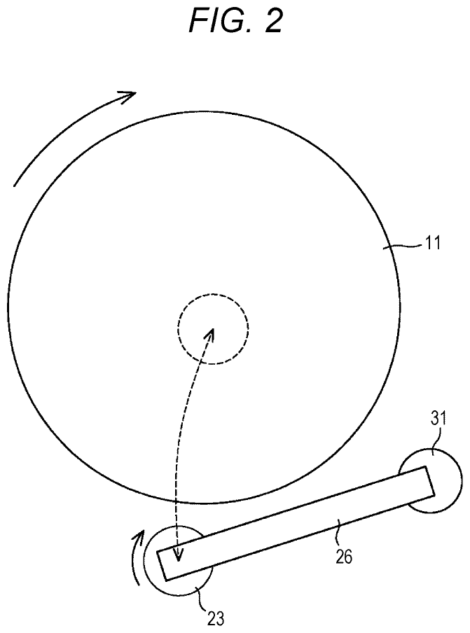

The dresser shaft 24 connecting the dresser 23 is rotatably supported by the dresser arm 26, and the dresser 23 moves (swings) along the radial direction of the polishing pad 11 as illustrated in FIG. 2 while being in contact with the polishing pad 11 by the dresser arm 26. A dresser control device 35 that calculates a sliding distance and a sliding speed of the dresser 23 is electrically connected to the dressing unit 14.

Abrasive grains such as diamond grains are fixed to the lower surface of the dresser 23. The portion to which the abrasive grains are fixed constitutes a dressing surface for dressing the polishing surface 11a of the polishing pad 11. As an aspect of the dressing surface, a circular dressing surface (dressing surface in which abrasive grains are fixed to the entire lower surface of the dresser 23), a ring-shaped dressing surface (dressing surface in which abrasive grains are fixed to the peripheral edge part of the lower surface of the dresser 23), or a plurality of circular dressing surfaces (dressing surface in which abrasive grains are fixed to surfaces of a plurality of small-diameter pellets arranged at substantially equal intervals around the center of the dresser 23) can be applied. Note that the dresser 23 in the present embodiment is provided with the circular dressing surface.

A film thickness sensor (film thickness measuring instrument) 38 for measuring the film thickness of the substrate W is disposed in the polishing table 12. The film thickness sensor 38 is disposed facing the surface of the substrate W held by the top ring 20. The film thickness sensor 38 is the film thickness measuring instrument that measures the film thickness of the substrate W while moving across the surface of the substrate W according to the rotation of the polishing table 12. As the film thickness sensor 38, a non-contact type sensor such as an eddy current sensor or an optical sensor can be used. The measurement value of the film thickness is sent to a control device (not illustrated), and a film thickness profile (film thickness distribution along the radial direction of the substrate W) of the substrate W is generated. The completion of polishing of the substrate W is determined based on the film thickness profile.

FIG. 2 is a diagram illustrating a movement range of the dresser 23. The dresser arm 26 turns clockwise and counterclockwise by a predetermined angle by driving of the motor 30. By the turning of the dresser arm 26, the dresser 23 moves in the radial direction of the polishing pad 11 within a range indicated by a dotted line in the drawing.

FIG. 3 is an explanatory diagram illustrating an outline of polishing of the substrate W and dressing of the polishing pad 11 by the dresser 23. The top ring 20 holds the substrate W on the lower surface and rotates in the direction of an arrow G about a rotation axis (not illustrated) to rotate the substrate W on the polishing pad 11. A retainer ring 39 is provided on an outer periphery of a lower end of the top ring 20, and annular belt-shaped pressure chambers M1 to M4 made of a membrane are formed inside the retainer ring 39. By adjusting the pressure of each of the pressure chambers M1 to M4, it is possible to control the pressing force of the substrate W being in contact with the portion to the polishing pad 11.

In FIG. 3, the dresser 23 comes into contact with the polishing table 12 and the polishing pad 11 rotating in the direction of an arrow A with a predetermined pressing force while rotating in the direction of an arrow C. In addition, dressing of the polishing pad 11 is performed while the dresser 23 moves in a D direction (radial direction of the polishing pad) in the drawing by swinging of the dresser arm 26 (refer to FIG. 2).

The movement range of the dresser 23 is divided into a plurality of (seven in the example of FIG. 3) scan areas (swing sections) S1 to S7. These scan areas S1 to S7 are virtual sections set in advance on the polishing surface 11a, and are arranged along the moving direction of the dresser 23 (that is, substantially the radial direction of the polishing pad 11). The dresser 23 performs dressing on the polishing pad 11 while moving across the scan areas S1 to S7. The lengths of the scan areas S1 to S7 may be the same as or different from each other. The dresser control device 35 measures the profile (polishing profile) of the polishing amount in the radial direction of the polishing pad 11 from the measurement value of the height of the polishing pad 11 in each of the scan areas S1 to S7 measured by the pad height sensor 32.

The moving speed of the dresser 23 when the dresser 23 swings on the polishing pad 11 is set in advance for each of the scan areas S1 to S7, and can be appropriately adjusted. In addition, the pressing force applied to the polishing pad 11 by the dresser 23 and the rotation speed of the dresser 23 are set in advance and can be appropriately adjusted. By increasing (decreasing) the moving speed of the dresser 23, a staying time of the dresser 23 on the polishing pad 11 becomes short (long), and as a result, the scraping amount of the polishing pad 11 becomes small (large). Further, as will be described later, by adjusting the pressing force by the dresser 23 and the rotation speed of the dresser 23, the scraping amount (and the cut rate) of the polishing pad 11 by the dresser 23 can be adjusted.

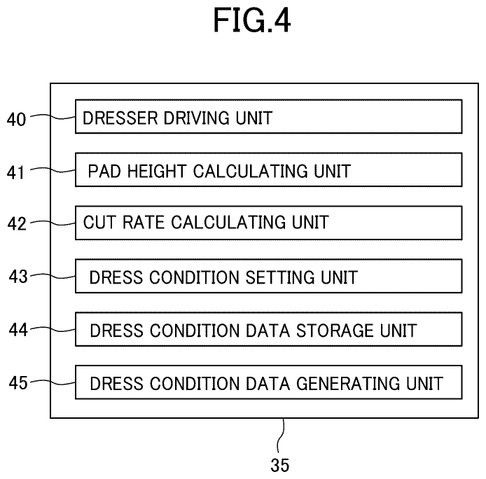

The dresser control device 35 is a dedicated or general-purpose computer, and includes functional blocks such as a dresser driving unit 40, a pad height calculating unit 41, a cut rate calculating unit 42, a dress condition setting unit 43, a dress condition data storage unit 44, and a dress condition data generation unit 45 as illustrated in FIG. 4. The dresser control device controls the operation of the dresser 23, and sets the dress condition based on the measurement value of the scraping amount (cut rate) of the polishing pad 11 such that the cut rate becomes constant.

The dresser driving unit 40 controls driving of various motors for driving the dresser 23, and controls driving of the dresser 23 under a preset condition (moving speed, dress load, and rotation speed).

The pad height calculating unit 41 calculates the height of the polishing pad 11 based on the measurement value by the pad height sensor 32. The height of the polishing pad 11 calculated by the pad height calculating unit 41 may be calculated for each of the scan areas S1 to S7, or may be calculated as an average value of the scan areas S1 to S7. The cut rate calculating unit 42 calculates, as the cut rate, a scraping amount (wear amount) of the polishing pad 11 at regular time intervals from a change in the height information of the polishing pad calculated by the pad height calculating unit 41.

The dress condition setting unit 43 sets dress conditions (pressing force and rotation speed of the dresser 23) of the polishing pad 11 by the dresser 23. The dress condition data storage unit 44 stores information on the cut rate corresponding to the dress condition. As will be described later, the dress condition data generation unit 45 generates a dress condition corresponding to a predetermined cut rate by interpolation or the like, and changes the dress condition to correct the change when the actual cut rate changes with the dressing.

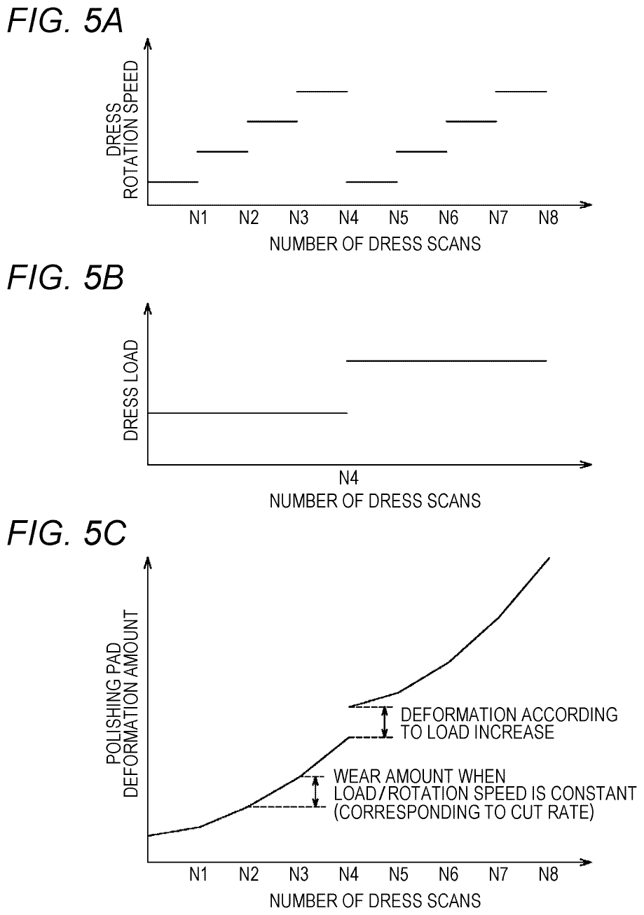

FIGS. 5A to 5C are explanatory diagrams illustrating an example of a dresser deformation amount (wear amount) when the dress load and the dress rotation speed are changed. In FIGS. 5A to 5C, a horizontal axis represents the number of times (the number of dress scans) of reciprocating movement (scanning) on the polishing pad 11 by the dresser 23, and the scraping amount (wear amount) of the polishing pad 11 increases as the number of dress scans increases. In FIGS. 5A to 5C, a case where the number of dress scans is divided into a plurality of sections (eight sections from 0 to N8) will be described as an example. One section of the number of dress scans is set so that the scraping amount of the polishing pad can be accurately measured before and after the section.

FIG. 5A illustrates an example in which the dress rotation speed is increased every time the number of dress scans reaches a certain value (N1 to N4), and this is repeated twice. FIG. 5B illustrates an example in which the dress load is increased when the number of dress scans reaches a certain value (N4). In each section (for example, a section in which the number of dress scans is 0 to N1) of the number of dress scans, the dress conditions (the pressing force by the dresser 23 and the rotation speed of the dresser 23) are constant. Further, in FIG. 5A, the value of the dress rotation speed in each section where the number of dress scans is between 0 and N4 and the value of the dress rotation speed in each section where the number of dress scans is between N4 and N8 are set to be the same value.

FIG. 5C is a graph illustrating an example of a measurement value of the deformation amount (change amount of the height of the polishing pad 11) of the polishing pad 11 when dressing is performed under the dress conditions (the pressing force by the dresser 23 and the rotation speed of the dresser 23) in FIGS. 5A and 5B. The deformation amount increases as the number of dress scans increases, indicating that the polishing pad 11 is gradually worn. In the example of FIG. 5C, the deformation amount of the polishing pad 11 is measured for a total of 8 dress conditions including 4 dress rotation speeds and 2 dress loads.

The deformation amount in each section indicates the wear amount of the polishing pad when the load and the rotation speed are constant, and since the dress conditions (the pressing force and the rotation speed by the dresser 23) in each section are constant, the cut rate is constant. Here, it is illustrated that the inclination of the deformation amount increases in each section where the number of dress scans is 0 to N4 (and each section where the number of dress scans is N4 to N8), and the cut rate increases as the dress rotation speed increases.

In FIG. 5C, for example, when a section in which the number of dress scans is N1 to N2 is compared with a section in which the number of dress scans is N5 to N6, the latter has a higher cut rate of the polishing pad. This is because the dress load is increased in the section where the number of dress scans is N5 to N6. The discontinuous deformation amount of the polishing pad when the number of dress scans becomes N4 is caused by an increase in the deformation amount of the polishing pad 11 according to an increase in the dress load. Therefore, in calculating the cut rate of the polishing pad, it is necessary to consider this deformation amount.

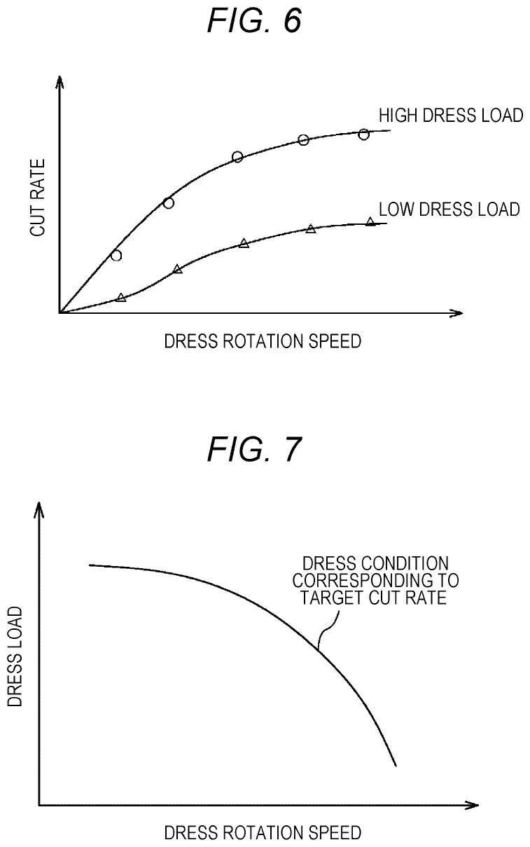

FIG. 6 is a graph in which the cut rate for each dress condition is calculated based on the graph of FIGS. 5A to 5C. The example of FIG. 6 illustrates a change in the cut rate with respect to a case where the dress rotation speed is changed (each section where the number of dress scans in FIGS. 5A to 5C is 0 to N4). In FIG. 6, a “low dress load” indicates a case where the dress load is low (the section where the number of dress scans is 0 to N4 in FIG. 5B), and a “high dress load” indicates a case where the dress load is high (the section where the number of dress scans is N4 to N8 in FIG. 5B). The graph of FIG. 6 illustrates that the cut rate tends to increase as the dress rotation speed and the dress load increase.

Here, a line (curve in FIG. 6) connecting each point (points indicated by circles and triangles in FIG. 6) of the dress rotation speed at which the cut rate has been measured can be calculated by an interpolation formula such as spline interpolation, for example. The approximate expressions of the dress rotation speed and the cut rate for each of the “low dress load” and the “high dress load” can be a form of data indicating the relationship between the dress rotation speed and the cut rate calculation value.

The cut rate calculating unit 42 changes the dress load and the dress rotation speed at the time of breaking in the polishing pad or at the time of replacement of the dresser to perform the dressing process on the polishing pad, calculates the cut rate from the measurement value of the scraping amount of the polishing pad, and stores data of the calculated cut rate in the dress condition data storage unit 44 in association with the dress load and the dress rotation speed. The dress condition data generation unit 45 calculates data indicating the relationship between the dress rotation speed and the cut rate calculation value with respect to the dress load by, for example, interpolation and stores the data in the dress condition data storage unit 44.

For example, in a case where the dressing process is performed under each condition of the dress load of 3 conditions (10N, 20N, 30N) and a dress rotation speed of 4 conditions (50 rpm, 60 rpm, 70 rpm, 80 rpm) to calculate the cut rate, data corresponding to 12 conditions is obtained. Using these data, the cut rate under an arbitrary condition (for example, 15N/65 rpm) within the condition can be calculated by interpolation. The data of the cut rate calculated in this manner is stored in the dress condition data storage unit 44 in association with the data of the corresponding dress condition.

Here, the break-in of the polishing pad refers to a step of attaching a new polishing pad to a polishing table and first performing only dressing (not polishing the substrate). After the normal break-in, a process of polishing (dummy polishing) the dummy substrate to make the pad suitable for polishing the substrate is performed. Since the substrate (product substrate) is not polished during the break-in, there is no undesirable influence on the polishing of the product substrate.

FIG. 7 is a graph illustrating an example of a relationship of dress conditions corresponding to a certain cut rate (target cut rate), and points on the graph correspond to the same target cut rate. The dress condition data generation unit 45 calculates a dress condition corresponding to a certain target cut rate by interpolation or the like based on the data (data of the cut rate corresponding to the dress condition) stored in the dress condition data storage unit 44. The dress condition setting unit 43 sets the dress condition corresponding to the target cut rate by determining the dress condition (the dress rotation speed and the dress load) corresponding to an arbitrary point on the graph. As a result, the polishing of the substrate after the dummy polishing can be started under the dress condition that achieves the target cut rate, and polishing process performance can be stabilized by eliminating individual differences of the dresser.

Here, even in a case where the dress condition is constant, the cut rate of the polishing pad 11 by the dresser 23 changes as the polishing proceeds and the dressing is overlapped. This occurs due to factors such as the abrasive grains on the dresser surface being rounded/clogged, and the polishing pad 11 containing moisture. Therefore, even when the set value of the dress condition is made constant, it is difficult to make the actual cut rate of the polishing pad constant.

Therefore, in the present embodiment, the change in the cut rate is suppressed by changing the dress condition corresponding to the target cut rate at a constant timing. In the present embodiment, the change rate of the current cut rate (calculated value) from the target cut rate is calculated, and the dress condition (dress load and dress rotational speed) is set such that the change rate decreases (or becomes zero) when the change rate exceeds the set value. Here, the change rate refers to a change rate between the cut rate (for example, it is lower than the initial state due to a change in the dresser) when dressing is performed under a certain dress condition in which polishing is progressing and the cut rate that can be acquired under the same dress condition from the data acquired by the method described in FIGS. 5A to 5C.

In the present embodiment, a case where the actual cut rate becomes 80% of the target cut rate (that is, as a result of overlaying the dressing with the substrate polishing process, the actual cut rate decreases by 20%) will be described as an example. The dress condition data generation unit 45 calculates the dress condition corresponding to the cut rate (=1/0.8) of 125% of the target cut rate from the data (data stored in the dress condition data storage unit 44 (data of the cut rate corresponding to the dress condition)) related to the dress condition and the cut rate acquired by the method described in FIGS. 5A to 5C by, for example, interpolation. Alternatively, the dress condition corresponding to the cut rate of 125% of the target cut rate may be determined on the basis of an approximate expression of the dress rotation speed or the dress load and the cut rate obtained from the data related to the dress condition and the cut rate.

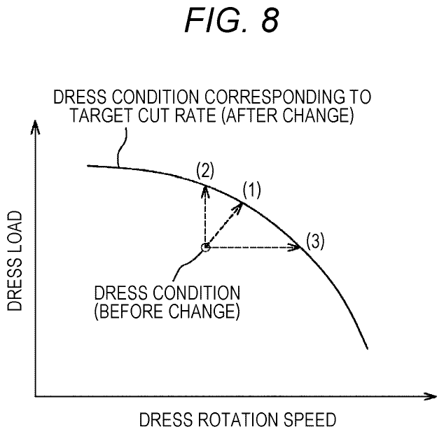

Alternatively, a plurality of dress conditions corresponding to the cut rate (target cut rate after change) of 125% of the target cut rate may be calculated from the data related to the dress condition and the cut rate stored in the dress condition data storage unit 44, an approximate expression between the dress rotation speed and the dress load may be obtained on the basis of the plurality of calculated dress conditions, and the optimum dress condition may be determined on the basis of the approximate expression. FIG. 8 is a graph illustrating an example of an aspect of changing to the dress condition corresponding to the target cut rate after the change. In the change of the dress condition, the dress condition in which the distance (Euclidean distance, Manhattan distance, or Chebyshev distance) to the curve of the dress condition after the change is minimized may be set ((1) in FIG. 8), only the dress load may be increased ((2) in FIG. 8), or only the dress rotation speed may be increased ((3) in FIG. 8).

Alternatively, the dress condition data generation unit 45 may correct the relationship data by multiplying the obtained cut rate by 0.8 in the data (relationship data) related to the dress condition and the cut rate acquired by the method described in FIGS. 5A to 5C. That is, the relationship data may be corrected on the basis of the change rate of the calculated cut rate from the target cut rate, and the dress condition for obtaining the target cut rate may be obtained on the basis of the corrected relationship data. When the relationship data is corrected so that the cut rate becomes 0.8 times, the dress condition (dress load, rotation speed) for obtaining the same cut rate (target cut rate) as that before the correction relatively increases.

Since the polishing progresses and (sharpness of) the dresser changes, when dressing is performed under the dress conditions obtained by the above method, the actual cut rate becomes the target cut rate (or a value close to the target cut rate). The parameter of the changed dress condition is stored in the dress condition data storage unit 44, and is changed (or corrected) to the dress condition for the target cut rate.

In addition to the case where the difference between the measurement value of the cut rate and the target value exceeds the predetermined value, the change of the dress condition may be performed in any case of when the number of polished substrates W reaches a predetermined value, when the wear amount of the polishing pad reaches a predetermined value, when a predetermined time elapses from the change of the dress condition immediately before, or when the polishing rate of the substrate decreases.

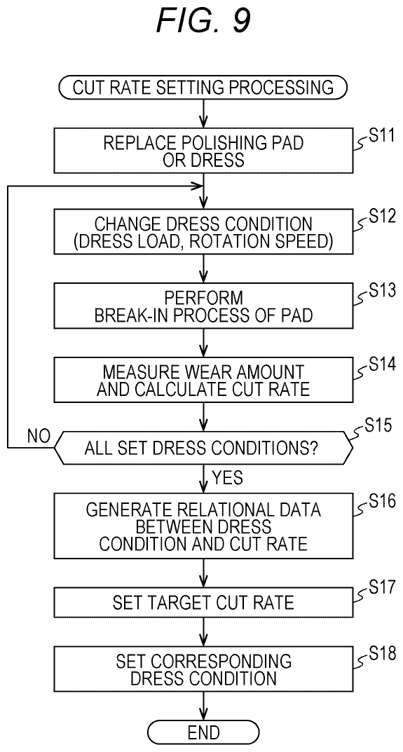

FIG. 9 is a flowchart illustrating an example of the cut rate setting processing in the polishing apparatus having the above configuration.

When the polishing pad or the dresser is replaced (Step S11), the dress condition setting unit 43 changes the dress condition (dress load, rotation speed) to a predetermined value (Step S12). Then, the dress control device 15 reciprocates the dresser 23 a predetermined number of times (the number of dress scans) to perform a break-in process of the polishing pad 11 (Step S13). Thereafter, the pad height calculating unit 41 measures the height of the polishing pad 11, and the cut rate calculating unit 42 calculates the cut rate (Step S14). Information on the calculated cut rate is stored in the dress condition data storage unit 44 in association with the dress condition. A determination is made as to whether the cut rate has been calculated for all combinations of the set dress conditions (dress load, rotation speed) (Step S15). In a case where the calculation has been performed (Y), the process proceeds to Step S16. Moreover, in a case where the calculation has not been performed (N), the process returns to Step S12, a different dress condition is set, and the cut rate is calculated.

In Step S16, the dress condition data generation unit 45 calculates and generates a cut rate corresponding to another dress condition by processing such as interpolation on the basis of the information of the calculated value of the cut rate for the set dress condition (dress load, rotation speed) stored in the dress condition data storage unit 44 (Step S16). Information of the calculated cut rate data is stored in the dress condition data storage unit 44 as relational data in association with the dress condition.

Thereafter, the dress condition setting unit 43 sets the cut rate (target cut rate) of the polishing pad 11 applied in the substrate polishing process (Step S17), and sets the corresponding dress condition (dress load, rotation speed) based on the data of the cut rate stored in the dress condition data storage unit 44 (Step S18).

In the present embodiment, the target cut rate is a predetermined cut rate, for example, empirically or in consideration of polishing performance or productivity by one polishing pad.

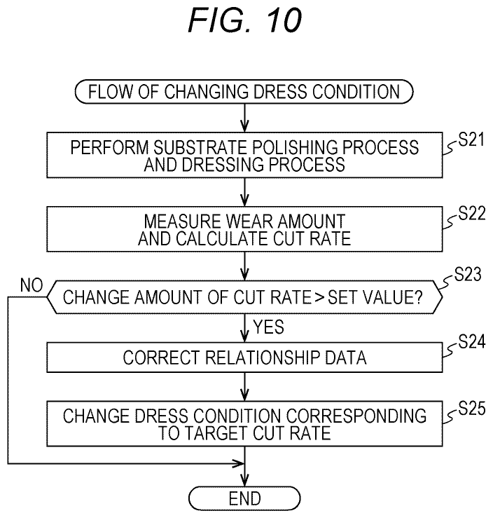

FIG. 10 is a flowchart illustrating an example of a flow of changing the dress condition. When the substrate polishing process is started, the substrate polishing apparatus drives the top ring 20 to polish the substrate W set in the apparatus until a predetermined film thickness is reached. Thereafter, the dresser 23 is driven to perform the dressing on the polishing pad 11 after the polishing process, whereby the polishing pad 11 is dressed (Step S21).

Thereafter, the pad height calculating unit 41 measures the height of the polishing pad 11, and the cut rate calculating unit 42 calculates the cut rate (Step S22). Note that the measurement of the cut rate in Step S22 may be obtained by measuring the pad height when the dressing after polishing is finished, and dividing the pad wear amount by the total dressing time until the pad wear amount reaches a predetermined pad wear amount.

Thereafter, it is determined whether or not a difference between the calculated cut rate and the target cut rate exceeds a set value. When the difference exceeds the set value (Y), it is determined that the cut rate of the polishing pad has decreased by repetition of the dressing process, and the relationship data is corrected so as to correspond to the decrease from the target cut rate (Step S24). Thereafter, the dress condition setting unit 43 changes the dress condition so that the decrease becomes 0 (while maintaining the value of the target cut rate) (Step S25). As a result, the actual cut rate can be suppressed from varying from the target cut rate.

Meanwhile, when the difference between the calculated cut rate and the target cut rate is within the set value (“N” in Step S22), it is determined that the cut rate of the polishing pad has not decreased, and the polishing process for the next substrate W is continued without changing the dress condition.

The target cut rate may be the cut rate (initial cut rate) measured in Step S14 corresponding to a predetermined (standard) dress condition. That is, although a value is not set in advance as the target cut rate, the dress condition may be corrected so that the initial cut rate can be obtained even when the dresser changes as the polishing progresses. As a result, since the cut rate can be stabilized while one dresser is used, the polishing performance can be stabilized.

In the flowchart of FIG. 9, the cut rate corresponding to another dress condition is calculated and generated in Step S16, and then the dress condition corresponding to the target cut rate is set. However, the dress condition corresponding to the cut rate close to the target cut rate may be set from the cut rates (Step S14) corresponding to the set dress condition. In this case, Step S16 is omitted.

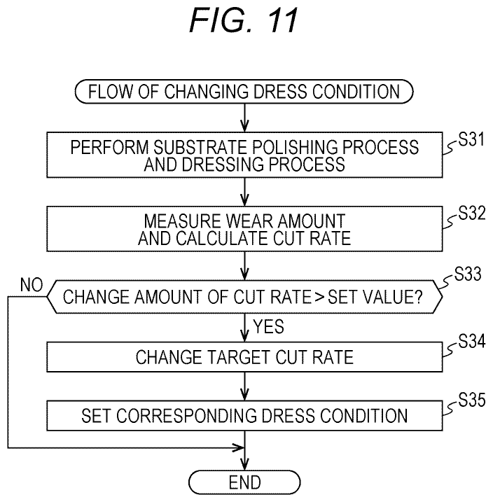

FIG. 11 is a flowchart illustrating an example of a flow of changing the dress condition in a case where the dress condition is changed by changing the target cut rate (the embodiment illustrated in FIG. 8). Since steps S31 and S32 are the same as steps S21 and S22 in FIG. 10, the description thereof is omitted. In Step S33, it is determined whether or not the difference between the calculated cut rate and the target cut rate exceeds a set value. When the set value is exceeded (Y), it is determined that the cut rate of the polishing pad has decreased by repetition of the dressing process, and the dress condition data generation unit 45 changes the target cut rate so that the decrease becomes 0 (Step S34). Then, the dress condition setting unit 43 sets the dress condition corresponding to the changed target cut rate (Step S35). As a result, the actual cut rate can be suppressed from varying from the target cut rate.

In the embodiment described above, the step of measuring the cut rate for each of the plurality of dress conditions is performed in the break-in process performed after the new pad is attached to the polishing table, but the present invention is not limited thereto. The process of measuring the cut rate may be performed while the polishing pad is being used as the polishing of the substrate progresses. The process of measuring the cut rate may be performed on the polishing pad after the polishing pad has been used to polish the substrate. Further, the step of measuring the cut rate for each of the plurality of dress conditions and the step of changing the dress conditions may be individually performed for each of the plurality of scan areas of the dresser. In addition, the present invention can be applied not only to the mode in which dressing is performed while the dresser swings on a polishing pad, but also to a mode in which the dresser having a relatively large diameter is used at a polishing pad-shaped fixed position.

The above-described embodiments have been described for the purpose of enabling a person having ordinary knowledge in the technical field to which the present invention belongs to implement the present invention. Various modifications of the above embodiment can be naturally made by those skilled in the art, and the technical idea of the present invention can also be applied to other embodiments. The present invention is not limited to the described embodiments, but is to be construed in the broadest scope according to the technical idea defined by the claims.

What is claimed is:

1. A substrate polishing method for polishing a substrate by bringing a polishing member used in a substrate polishing apparatus into contact with the substrate, the substrate polishing method comprising:
performing a first dressing of dressing the polishing member under a plurality of preset dress conditions;
measuring a first cut rate of the polishing member based on a measurement value of a surface height of the polishing member for each set dress condition;
storing the set dress condition and the first cut rate in association with each other as relationship data;
polishing a substrate by applying a first dress condition corresponding to a target cut rate, and measuring a second cut rate of the polishing member based on the measurement value of the surface height of the polishing member;
correcting the relationship data based on a change of the second cut rate from the target cut rate, and acquiring a second dress condition corresponding to the target cut rate based on the corrected relationship data; and
polishing the substrate by applying the second dress condition.

2. The substrate polishing method according to claim 1, wherein a cut rate corresponding to a dress condition different from the set dress condition is calculated based on the set dress condition and the first cut rate, and is stored as the relationship data.

3. The substrate polishing method according to claim 1, wherein the target cut rate is a predetermined value.

4. The substrate polishing method according to claim 1, wherein the target cut rate is the first cut rate acquired when the first dressing is performed by applying a predetermined first dress condition.

5. The substrate polishing method according to claim 1, wherein the second dress condition is acquired when a change rate of the second cut rate from the target cut rate exceeds a predetermined value.

6. The substrate polishing method according to claim 1, wherein the dress condition includes a rotation speed and a dress load of the dresser.

7. The substrate polishing method according to claim 6, wherein the second dress condition is set by correcting both the rotation speed and the dress load of the dresser.

8. A substrate polishing method for polishing a substrate by bringing a polishing member used in a substrate polishing apparatus into contact with the substrate, the substrate polishing method comprising:
performing a first dressing of dressing the polishing member under a plurality of preset dress conditions;
measuring a first cut rate of the polishing member based on a measurement value of a surface height of the polishing member for each set dress condition;
storing the set dress condition and the first cut rate in association with each other as relationship data;
polishing a substrate by applying a first dress condition corresponding to a target cut rate, and measuring a second cut rate of the polishing member based on the measurement value of the surface height of the polishing member;
changing the target cut rate based on a change of the second cut rate from the target cut rate, and acquiring a second dress condition based on the relationship data corresponding to the target cut rate after the change; and
polishing the substrate by applying the second dress condition.

9. The substrate polishing method according to claim 8, wherein a cut rate corresponding to a dress condition different from the set dress condition is calculated based on the set dress condition and the first cut rate, and is stored as relationship data.

10. The substrate polishing method according to claim 8, wherein the target cut rate is a predetermined value.

11. The substrate polishing method according to claim 8, wherein the target cut rate is the first cut rate acquired when the first dressing is performed by applying a predetermined first dress condition.

12. The substrate polishing method according to claim 8, wherein the second dress condition is acquired when a change rate of the second cut rate from the target cut rate exceeds a predetermined value.

13. The substrate polishing method according to claim 8, wherein the dress condition includes a rotation speed and a dress load of the dresser.

14. The substrate polishing method according to claim 13, wherein the second dress condition is set by correcting both the rotation speed and the dress load of the dresser.

15. A substrate polishing apparatus for polishing a substrate by bringing the substrate into sliding contact with a polishing member, the substrate polishing apparatus comprising:
a dresser that performs a first dressing for dressing the polishing member under a plurality of preset dress conditions;
a cut rate measurement unit that measures a first cut rate of the polishing member based on a measurement value of a surface height of the polishing member for each set dress condition;
a storage unit that stores the set dress condition and the first cut rate in association with each other as relationship data;
a dress condition setting unit that sets a dress condition of the dresser; and
a dress condition data generation unit that generates a second dress condition corresponding to the target cut rate,
wherein the substrate is polished by applying a first dress condition corresponding to a target cut rate, a second cut rate of the polishing member is measured based on the measurement value of the surface height of the polishing member, the relationship data is corrected based on a change of the second cut rate from the target cut rate, and the second dress condition corresponding to the target cut rate is generated based on the corrected relationship data, and
the substrate is polished by applying the second dress condition.

16. A substrate polishing apparatus for polishing a substrate by bringing the substrate into sliding contact with a polishing member, the substrate polishing apparatus comprising:
a dresser that performs a first dressing for dressing the polishing member under a plurality of preset dress conditions;
a cut rate measurement unit that measures a first cut rate of the polishing member based on a measurement value of a surface height of the polishing member for each set dress condition;
a storage unit that stores the set dress condition and the first cut rate in association with each other as relationship data;
a dress condition setting unit that sets a dress condition of the dresser; and
a dress condition data generation unit that generates a second dress condition corresponding to the target cut rate,
wherein the substrate is polished by applying a first dress condition corresponding to a target cut rate, a second cut rate of the polishing member is measured based on the measurement value of the surface height of the polishing member, the target cut rate is changed based on a change of the second cut rate from the target cut rate, and generating the second dress condition is generated based on the relationship data corresponding to the changed target cut rate, and
the substrate is polished by applying the second dress condition.
